(19) United States
(12) Patent Application Publication
(10) Pub. No.: US 2022/0285488 A1
(43) Pub. Date: Sep. 8, 2022

(54) SUPERJUNCTION SEMICONDUCTOR DEVICE HAVING FLOATING REGION AND METHOD OF MANUFACTURING SAME

(71) Applicant: DB HiTek Co., Ltd., Bucheon-si (KR)

(72) Inventors: Myeong Bum PYUN, Incheon (KR); Won Kook CHO, Bucheon-si (KR)

(21) Appl. No.: 17/584,891

(22) Filed: Jan. 26, 2022

(30) Foreign Application Priority Data
Mar. 3, 2021 (KR) 10-2021-0027820

(51) Int. Cl. H01L 29/06; H01L 29/10; H01L 29/08

(52) U.S. Cl. CPC H01L 29/0634; H01L 29/1095; H01L 29/086

(57) ABSTRACT

Disclosed are a superjunction semiconductor device having a floating region and a method of manufacturing the same. More particularly, a superjunction semiconductor device having a floating region and a method of manufacturing the same are disclosed, in which a floating region including first conductivity type impurities is between adjacent pillars in a ring region, so that an electric field can easily expand in the ring region under an N-rich condition, thereby improving breakdown voltage (BV) characteristics and ensuring device stability.

### CROSS REFERENCE TO RELATED APPLICATION

The present application claims priority to Korean Patent Application No. 10-2021-0027820, filed Mar. 3, 2021, the entire contents of which are incorporated herein for all purposes by this reference.

### BACKGROUND OF THE INVENTION

### Field of the Invention

The present disclosure relates to a superjunction semiconductor device having a floating region and a method of manufacturing the same. More particularly, the present disclosure relates to a superjunction semiconductor device having a floating region and a method of manufacturing the same, in which a floating region comprising first conductivity type impurities is between adjacent pillars in a ring region, so that an electric field can easily expand in the ring region under an N-rich condition, thereby improving breakdown voltage (BV) characteristics and ensuring device stability.

### Description of the Related Art

In general, a high-voltage semiconductor device, such as a power metal-oxide-semiconductor field-effect transistor (MOSFET) and an insulated gate bipolar transistor (IGBT), includes a source and a drain that are above and below a drift region, respectively. In addition, the high-voltage semiconductor device includes a gate insulating layer above the drift region adjacent to the source, and a gate electrode on the gate insulating layer. When the high-voltage semiconductor device is on, the drift region provides a conductive path through which a drift current flows from the drain to the source. When the high-voltage semiconductor device is off, the drift region provides a depletion region that may expand vertically in response to an applied reverse bias voltage.

The characteristics of the depletion region provided by the drift region determine the breakdown voltage of the high-voltage semiconductor device. In the above described high-voltage semiconductor device, to minimize conduction loss when the device is on, to ensure fast switching speed, research has been conducted on reducing the resistance of the drift region serving as a conductive path when the device is on. It is generally known in the art that the turn-on resistance of the drift region can be reduced by increasing the concentration impurities in the drift region. However, when the concentration of impurities in the drift region increases, space charges also increase in the drift region, thereby reducing the breakdown voltage of the device.

As a solution to this drawback, high-voltage semiconductor devices having a superjunction structure have been proposed to ensure a high breakdown voltage while reducing resistance when turned on.

FIG. 1 is a cross-sectional view illustrating a superjunction semiconductor device 9 according to the related art, and FIG. 2 is a graph illustrating a breakdown voltage as a function of the dose ratio of impurities in a semiconductor device (e.g., the superjunction semiconductor device 9 in FIG. 1).

Referring to FIG. 1, the superjunction semiconductor device 9 has a structure in which a plurality of first conductivity type pillars 930 are arranged in a transverse direction in a second conductivity type epitaxial layer 910. A depletion layer forms along the junction between the epitaxial layer 910 and the pillar 930. In this structure, the depletion layer easily expands laterally, so that a drift region in the epitaxial layer 910 and the pillar 930 is completely depleted. As a result, the concentration of the electric field E is relieved as it expands over a wide area. Therefore, a high breakdown voltage (BV) is ensured, thereby improving the forward characteristic of the device 9.

However, referring to FIGS. 1 and 2, under an N-rich condition (e.g., inclusion of an excess of N-type impurities during growth of the epitaxial layer 910), it may be difficult to expand the electric field E in the ring region R As a result, as the area of the depletion layer decreases, a breakdown voltage BV1 decreases. This inevitably results in a deterioration of the characteristics of the device.

To solve the above problems, the present inventors disclosure have created a novel superjunction semiconductor device having a first conductivity type floating region and a method of manufacturing the same.

The foregoing is intended merely to aid in the understanding of the background of the present disclosure, and is not intended to mean that the present disclosure falls within the purview of the related art that is already known to those skilled in the art.

### DOCUMENTS OF RELATED ART

(Patent document 1) Korean Patent Application Publication No. 10-2005-0052597 “Superjunction semiconductor device”

### SUMMARY OF THE INVENTION

Accordingly, the present disclosure has been made keeping in mind the above problems occurring in the related art, and an objective of the present disclosure is to provide a superjunction semiconductor device having a floating region and a method of manufacturing the same, in which a floating region comprising first conductivity type impurities is between adjacent pillars in a ring region, so that an electric field can easily expand in the ring region under an N-rich condition, thereby improving breakdown voltage (BV) characteristics and improving device characteristics.

Another objective of the present disclosure is to provide a superjunction semiconductor device having a floating region and a method of manufacturing the same, in which the floating region (or the epitaxial layer or the device) has a dose ratio of impurities (e.g., P-type to N-type) equal to or less than 1, thereby preventing device characteristics from deteriorating when breakdown voltage decreases (e.g., under an N-rich condition).

In order to achieve the above objectives, the present disclosure may be implemented by embodiments having one or more of the following configurations.

According to one embodiment of the present disclosure, there is provided a superjunction semiconductor device, including a substrate; first and second epitaxial layers on the substrate, the first epitaxial layer in a cell region and the second epitaxial layer in a ring region; a plurality of pillars spaced apart from each other in a transverse direction in the first epitaxial layer and the second epitaxial layer, and which may extend by a predetermined distance or have a predetermined length in a longitudinal direction; a body region on each of the pillars in the first epitaxial layer; a source in each of the body regions; a gate electrode on the first epitaxial layer; and a floating region in the second epitaxial layer between adjacent pillars in the ring region.

According to another embodiment of the present disclosure, the floating region may have substantially a same doping concentration as the pillars.

According to another embodiment of the present disclosure, the floating region may have a predetermined length along a longitudinal direction in the ring region. The predetermined length of the floating region may be less than that of the adjacent pillars along the longitudinal direction in the ring region.

According to another embodiment of the present disclosure, the floating region may be in the ring region at a position adjacent to the cell region.

According to another embodiment of the present disclosure, the floating region may have an end that is adjacent to or in contact with a boundary between the ring region and the cell region (e.g., when the floating region is in a Y region or a corner of the ring region).

According to another embodiment of the present disclosure, there is provided a superjunction semiconductor device, including a substrate; a second conductivity type epitaxial layer on the substrate, including a first epi-layer in a cell region and a second epi-layer in a ring region; a plurality of first conductivity type pillars alternating with portions of the epitaxial layer, spaced apart from each other in a transverse direction in the first epi-layer and the second epi-layer, and which may extend a predetermined distance in a longitudinal direction; a first conductivity type body region on each of the pillars in the first epi-layer; a second conductivity type source in each of the body regions; a gate electrode on the first epi-layer; and a floating region in the second epi-layer between adjacent pillars in the ring region. The floating region may have an uppermost surface that is substantially flush with upper ends of the adjacent pillars and a vertical thickness or depth that is equal to or less than half of that of the adjacent pillars.

According to another embodiment of the present disclosure, the floating region may have a dose ratio of impurities (e.g., P-type to N-type impurities) that is equal to or less than 1.

According to another embodiment of the present disclosure, the superjunction semiconductor device may further include a body contact in the body region adjacent to or in contact with the source; and a gate oxide layer between the gate electrode and the first epi-layer.

According to another embodiment of the present disclosure, the floating region may also be adjacent to the cell region, and a length of the floating region in the longitudinal direction may be less than that of the adjacent pillars in the longitudinal direction (e.g., when the floating region is in a Y region or a corner of the ring region).

According to another embodiment of the present disclosure, there is provided a method of manufacturing a superjunction semiconductor device, the method including forming a first epitaxial layer and a second epitaxial layer on a substrate; forming a plurality of pillars in the epitaxial layer, spaced apart from each other in a transverse direction; forming a gate oxide layer on the first epitaxial layer; forming a gate electrode on the gate oxide layer; and forming a floating region between adjacent pillars in the second epitaxial layer. The floating region may be formed at a position corresponding to upper portions of the adjacent pillars.

According to another embodiment of the present disclosure, the floating region may be formed contemporaneously with the pillars.

According to another embodiment of the present disclosure, an upper end of the floating region may be substantially flush (e.g., at a same height or level) with upper ends of the adjacent pillars, and a vertical thickness or depth of the floating region may be less than that of the adjacent pillars. According to another embodiment of the present disclosure, a length of the floating region in a longitudinal direction may be less than that of the adjacent pillars in the longitudinal direction.

According to another embodiment of the present disclosure, the floating region may not have a length in the transverse direction when the floating region is in a corner in the ring region or adjacent to the corner.

According to another embodiment of the present disclosure, there is provided a method of manufacturing a superjunction semiconductor device, the method including forming a second conductivity type epitaxial layer including a first epitaxial layer and a second epitaxial layer on a substrate; forming a plurality of first conductivity type pillars in the epitaxial layer, spaced apart from each other in a transverse direction; forming a gate oxide layer on the first epitaxial layer; forming a gate electrode on the gate oxide layer; and forming a first conductivity type floating region between adjacent pillars in the second epitaxial layer. The floating region may be adjacent to a cell region and may have a dose ratio of impurities equal to or less than 1.

According to another embodiment of the present disclosure, the floating region may have a predetermined length equal to or less than half of that of the adjacent pillars (e.g., in a Y region or a corner of the ring region), an upper end of the floating region is substantially flush with upper ends of the adjacent pillars, and/or a vertical thickness or depth of the floating region is equal to or less than half of that of the adjacent pillars.

According to another embodiment of the present disclosure, the method may further include forming a second conductivity type source in each body region; and forming a first conductivity type body contact adjacent to or in contact with the source. The body contact may be formed in a center of the source, thereby separating the source into two source regions in the transverse direction.

The above configurations have one or more of the following effects.

Under the N-rich condition, the floating region comprising first conductivity type impurities is formed between adjacent pillars in the ring region, so that the electric field can easily expand in the ring region, thereby improving breakdown voltage (BV) characteristics and improving device characteristics.

In addition, the floating region has a dose ratio of impurities equal to or less than 1, thereby preventing device characteristics from deteriorating when the breakdown voltage decreases under a P-rich condition.

Meanwhile, the effects of the present disclosure are not limited to the effects described above and other effects not stated can be understood from the following description and claims.

### BRIEF DESCRIPTION OF THE DRAWINGS

The above and other objectives, features, and other advantages of the present disclosure will be more clearly understood from the following detailed description when taken in conjunction with the accompanying drawings, in which:

FIG. 1 is a cross-sectional view illustrating a superjunction semiconductor device according to the related art;

FIG. 2 is a graph illustrating a breakdown voltage as a function of the dose ratio of impurities in a semiconductor device;

FIG. 3 is a partial plan view illustrating a superjunction semiconductor device having a floating region, according to one or more embodiments of the present disclosure;

FIG. 4 is a cross-sectional view illustrating the superjunction semiconductor device according to an embodiment of the present disclosure;

FIG. 5 is a cross-sectional view illustrating a superjunction semiconductor device according to another embodiment of the present disclosure;

FIG. 6 is a graph illustrating a breakdown voltage as a function of the dose ratio of impurities in the superjunction semiconductor device according to the present disclosure; and

FIGS. 7 to 9 are views illustrating a method of manufacturing a superjunction semiconductor device having a floating region, according to one or more embodiments of the present disclosure.

### DETAILED DESCRIPTION OF THE INVENTION

Hereinafter, embodiments of the present disclosure will be described in more detail with reference to the accompanying drawings. The embodiments of the present disclosure can be modified in various forms. Therefore, the scope of the disclosure should not be construed as being limited to the following embodiments, but should be construed on the basis of the descriptions in the appended claims. The embodiments of the present disclosure are provided for complete disclosure of the present disclosure and to fully convey the scope of the present disclosure to those ordinarily skilled in the art.

As used herein, when an element (or layer) is referred to as being on another element (or layer), it can be directly on the other element, or one or more intervening elements or layers may be therebetween. In contrast, when an element is referred to as being directly on or above another component, intervening element(s) are not therebetween. Note that the terms “on”, “above”, “below”, “upper”, “lower”, etc. are intended to describe one element's relationship to one or more other element(s) as illustrated in the figures.

While the terms “first”, “second”, “third”, etc. may be used herein to describe various items such as various elements, regions and/or parts, these items should not be limited by these terms.

When a certain embodiment may be implemented differently, a specific process order may be performed differently from the described order. For example, two consecutively described processes may be performed substantially at the same time or performed in an order opposite to the described order.

The term “metal-oxide-semiconductor (MOS)” used herein is a general term. “M” is not limited to only metal, and may include various types of conductors. “S” may be a substrate or a semiconductor structure. “0” is not limited to only oxide and may include various types of organic or inorganic dielectric or insulator materials.

In addition, the conductivity type or doped region of the elements may be defined as “P-type” or “N-type” according to the main carrier characteristics. However, this is only for convenience of description, and the technical spirit of the present disclosure is not limited to the above-mentioned examples. For example, “P-type” or “N-type” may be replaced with the more general terms “first conductivity type” or “second conductivity type” hereinafter, where “first conductivity type” may refer to P-type, and “second conductivity type” may refer to N-type.

It should be further understood that terms such as “heavily doped” and “lightly doped” representing the doping concentration of an impurity region refer to the relative concentrations of dopant elements in the impurity region.

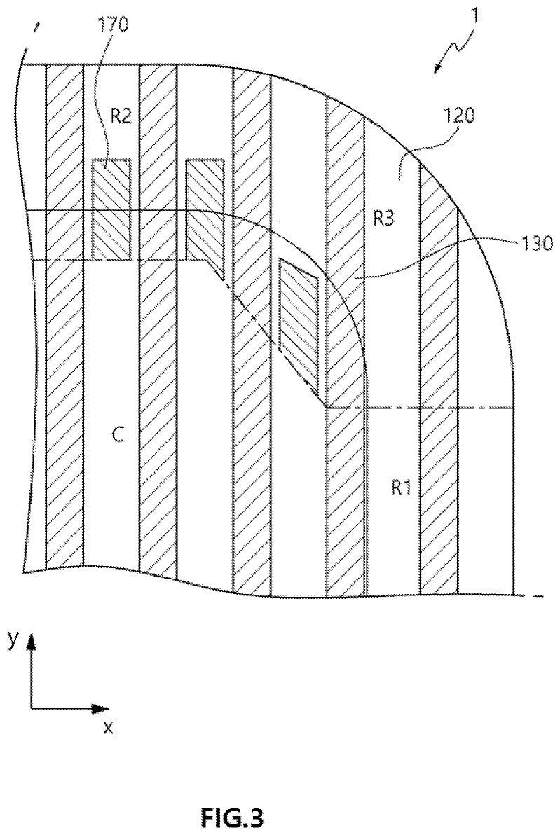

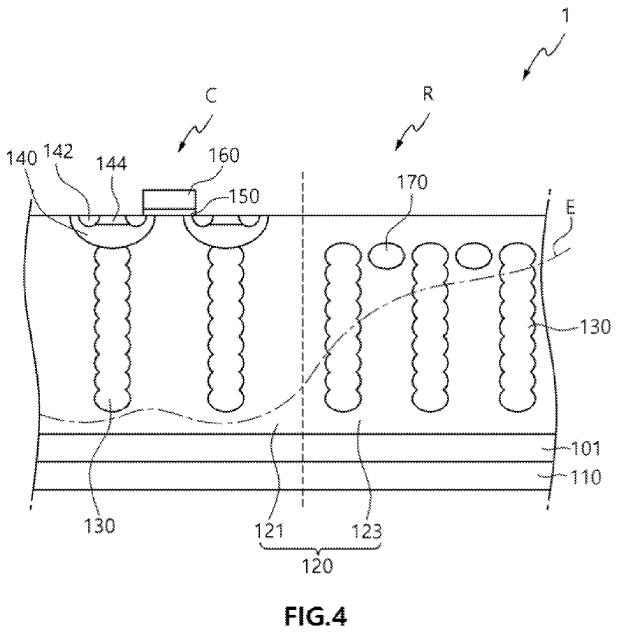

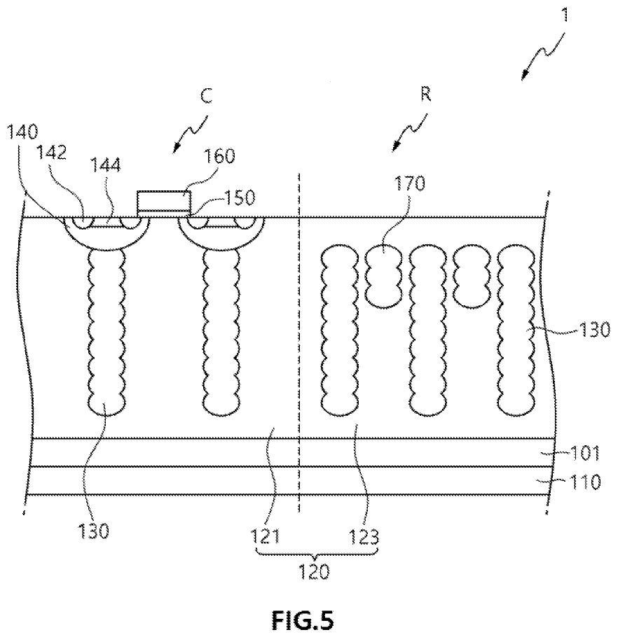

FIG. 3 is a partial plan view illustrating a superjunction semiconductor device 1 having a floating region, according to one or more embodiments of the present disclosure, FIG. 4 is a cross-sectional view illustrating the superjunction semiconductor device 1 according to an embodiment of the present disclosure, and FIG. 5 is a cross-sectional view illustrating a superjunction semiconductor device 1 according to another embodiment of the present disclosure.

Hereinafter, the superjunction semiconductor device 1 having the floating region according to the present disclosure will be described in detail with reference to the accompanying drawings.

Prior to describing the present disclosure in detail, a layout structure of the superjunction semiconductor device 1 according to the present disclosure will be described.

Referring to FIG. 3, the superjunction semiconductor device 1 according to the present disclosure includes a cell region C serving as an active region at the center of the device 1, and a ring region R (R1, R2, and R3) serving as a termination region that surrounds the cell region C. In the following description, in the ring region R, an end portion thereof along the x-axis direction is referred to as a ring X region R1, an end portion thereof along the Y-axis direction is referred to as a ring Y region R2, and a portion thereof connecting the ring X region R1 and the ring Y region R2 to each other is referred to as a ring corner region R3. The ring corner region R3 may have one or more curved sides or edges (and, when the corner region R3 contains more than one curved side or edge, they may be parallel to each other), but is not limited thereto.

In addition, although a transition region is formed between the cell region C and the ring region R, a detailed description thereof will be omitted for convenience of description. Also, the x-axis direction is referred to as a “transverse direction” and the Y-axis direction is referred to as a “longitudinal direction”. In addition, when the dose ratio of first conductivity type impurities to second conductivity type impurities in the device is less than 1, this may be referred to as an “N-rich” condition, and when the dose ratio of first conductivity type impurities to second conductivity type impurities exceeds 1, this may be referred to as a “P-rich” condition. Also, the term “epi-layer” may refer to an epitaxial layer or a part, portion or section thereof.

Referring to FIGS. 4 and 5, the superjunction semiconductor device 1 according to the present disclosure is characterized in that under the N-rich condition, a floating region comprising first conductivity type impurities is formed between adjacent pillars in the ring region R, so that an electric field E can easily expand in the ring region R, thereby improving breakdown voltage BV characteristics and ensuring device stability. It should be noted that the superjunction semiconductor device 1 according to the present disclosure may be limited to one having an N-rich epitaxial layer 120 (i.e., in which the dose or concentration of N-type dopants is greater than the dose or concentration of P-type dopants).

A substrate 101 comprising, for example, a silicon substrate, supports the device 1 (FIGS. 4-5). The substrate 101 may include a bulk wafer or an epitaxial layer. The substrate 101 may comprise, for example, a heavily doped second conductivity type substrate.

A drain electrode 110 may be formed on a surface of the substrate 101 opposite from the device 1.

An epitaxial layer 120 comprising lightly doped second conductivity type impurities, may be on the substrate 101 across the cell region C and the ring region R In the following description, for convenience of explanation, the epitaxial layer 120 in the cell region C may be referred to as a first epitaxial layer 121, and the epitaxial layer 120 in the ring region R may be referred to as a second epitaxial layer 123. A plurality of pillars 130 are in the epitaxial layer 120. The pillars 130 include first conductivity type impurities. In the epitaxial layer 120, the pillars 130 are spaced apart from each other along the transverse direction while extending along the longitudinal direction. The pillars 130 are formed in both the cell region C and the ring region R Unlike as illustrated in FIG. 4, the first pillars 111 arranged in the ring region R may be formed such that upper ends thereof are connected to each other.

The pillars 130 alternate with portions of the epitaxial layer 120 in the transverse (x-axis) direction as shown in FIG. 3, and may extend downward in the epitaxial layer 120 in the vertical (e.g., y-axis) direction as shown in FIGS. 4-5. Alternatively or additionally, as illustrated in FIG. 4, the pillars 130 may have contact surfaces with the epitaxial layer 120 that are curved in opposite directions, but these structures are not limited thereto.

A body region 140, which is a first conductivity type impurity region, may be on the pillars 130 in the first epitaxial layer 121 in the cell region C. One body region 140 is on each pillar 130 in the cell region C, and may have a predetermined width in the transverse direction (FIGS. 4-5). A source 142, which is a heavily doped second conductivity type impurity region, may be in each of the body regions 140. Two sources 142 may be in each of the body regions 140, separated in the transverse direction by a body contact 144, but the sources 142 are not limited thereto. The body contact 144 may be in the body region 140 adjacent to or in contact with the source(s) 142.

A gate oxide layer 150 is on the first epitaxial layer 121, under a gate electrode 160. The gate oxide layer 150 may be or comprise a silicon oxide layer, a high-k dielectric layer, or a combination thereof, but is not limited thereto. Additional insulating layers (not shown) may cover an upper surface and side surfaces of the gate electrode 160. The gate electrode 160 is on the gate oxide layer 150. The gate electrode 160 may be or comprise conductive polysilicon, a metal, a conductive metal nitride, a refractory metal silicide, or a combination thereof.

A floating region 170 is in the second epitaxial layer 123 between adjacent pillars 130 in the ring Y region R2 and/or the ring corner region R3, and optionally in the ring X region R1. The floating region 170 includes first conductivity type impurities, and preferably has substantially the same doping concentration as the pillars 130.

Hereinafter, the structure of a superjunction semiconductor device 9 according to the related art and its problems, and the structure of the superjunction semiconductor device 1 according to the present disclosure for solving the problems will be described.

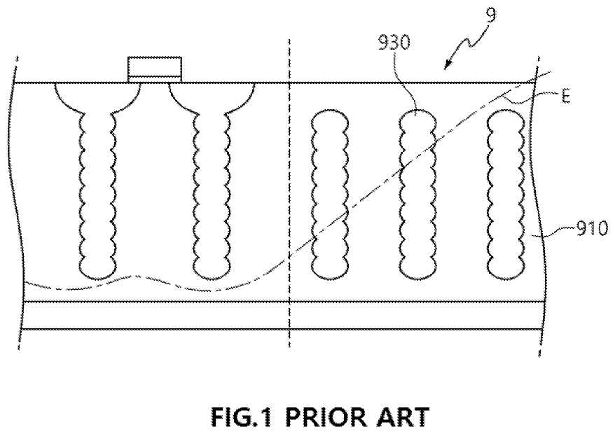

Referring to FIG. 1, the superjunction semiconductor device 9 has a structure in which a plurality of first conductivity type pillars 930 are arranged in the transverse direction in an epitaxial layer 910, which includes second conductivity type impurities. A depletion layer is formed along the junction of the epitaxial layer 910 and the pillar 930 under certain conditions. In this structure, the depletion layer easily expands laterally, so that a drift region in the epitaxial layer 910 (e.g., between and/or below the pillars 930) is completely depleted. As a result, the concentration of an electric field E is relieved as it expands over a wide area. Therefore, a high breakdown voltage (BV) is ensured, thereby improving the forward characteristic of the device.

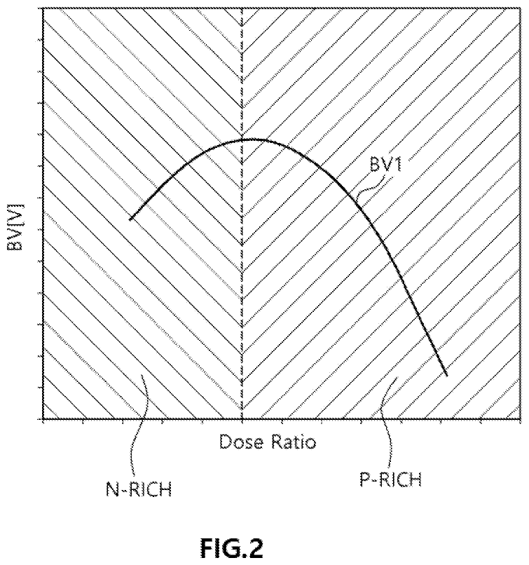

However, referring to FIGS. 1 and 2, under the N-rich condition, the electric field E may be difficult to expand in a ring region R Therefore, the area of the electric field E decreases in the ring region R, leading to a reduction in a breakdown voltage BV1. This inevitably results in a deterioration of the characteristics of the device.

To avoid such a problem, referring to FIGS. 4 and 5, the superjunction semiconductor device 1 according to embodiments of the present disclosure includes the floating region 170 in the second epitaxial layer 123 between adjacent pillars 130 in the ring Y region R2 and/or the ring corner region R3, and optionally in the ring X region R1.

Referring to FIG. 3, the floating region 170 may extend by a predetermined length in the longitudinal direction in the ring region R. For example, the length of the floating region 170 in the longitudinal direction is preferably less than that of adjacent pillars 130 in the longitudinal direction in the ring region R, and is more preferably equal to or less than about half of that of the adjacent pillars 130.

For example, when the floating region 170 is in the ring Y region R2, the length thereof may be equal to or less than half of that of the adjacent pillars 130 in the ring Y region R2. Similarly, when the floating region 170 is formed in the ring corner region R3, the length thereof may be equal to or less than half of that of the adjacent pillars 130 in the ring corner region R3.

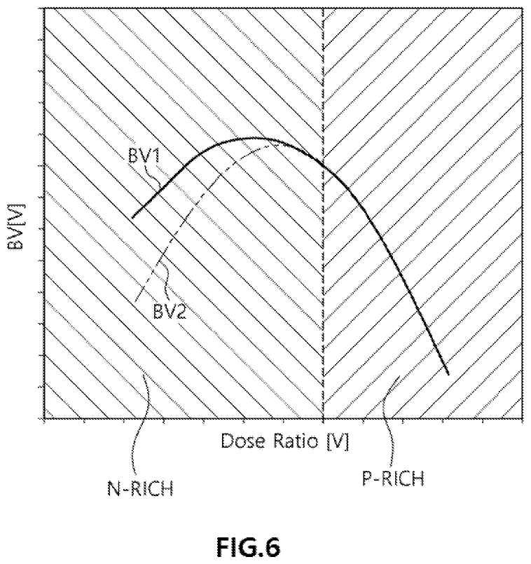

In addition, the floating region 170 is preferably in the ring region Rat a position adjacent to the cell region C. For example, when the floating region 170 is in the ring Y region R2 or the ring corner region R3, the floating region 170 may have an end adjacent to or in contact with the boundary between the ring region R and the cell region C. This is because expansion of the electric field E is facilitated when the floating region 170 is adjacent to the cell region C. That is, in the presence of the floating regions 170 in the ring region R, the electric field E may easily extend to an outer portion of the ring region R Referring to FIGS. 4 and 5, the floating region 170 may extend into the epitaxial layer 120 by a predetermined distance (e.g., have a predetermined height), as measured from an uppermost surface of the adjacent pillars 130. For example, the uppermost surface of the floating regions 170 may be substantially flush (e.g., coplanar) with the uppermost surface of the adjacent pillars 130, but the height of the floating regions 170 may be equal to or less than half of that of the adjacent pillars 130. This is because, when the floating region 170 has an area or height equal to or greater than a predetermined level (e.g., > half of the height or area of the adjacent pillars 130), the breakdown voltage (BV) may decrease when the P-rich condition is satisfied (e.g., the device 1 or the epitaxial layer 120 has more P-type impurities and N-type impurities), resulting in a deterioration of device characteristics. That is, the floating region 170 preferably has a dose ratio of impurities (e.g., equal to or less than 1. FIG. 6 is a graph illustrating a breakdown voltage as a function of the dose ratio of impurities in the superjunction semiconductor device 1 according to the present disclosure.

Referring to FIG. 6, when using the superjunction semiconductor device 1 according to the present disclosure, the breakdown voltage BV2 is less than the breakdown voltage BV1 in the superjunction semiconductor device 9 according to the related art (i.e., without the floating regions 170) at the same dose ratio under nearly all N-rich conditions, (e.g., compared to an otherwise identical device 9 according to the related art). Therefore, the device characteristics are improved.

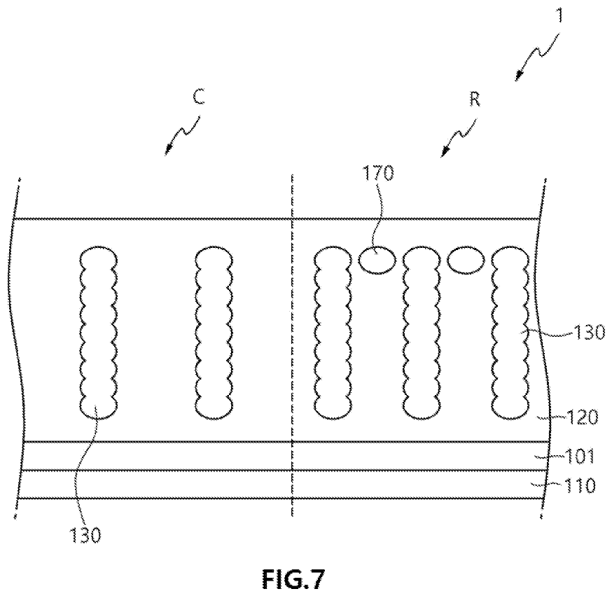

FIGS. 7 to 9 are views illustrating a method of manufacturing a superjunction semiconductor device having a floating region, according to one or more embodiments of the present disclosure.

Hereinafter, the method of manufacturing the superjunction semiconductor device having the floating region according to the present disclosure will be described in detail with reference to the accompanying drawings. It should be noted that the steps of forming each configuration may performed in an order different than presented, or may be performed substantially simultaneously. In addition, the methods of forming each configuration are only for convenience of description, and the scope of the present disclosure is not limited by the following examples.

First, referring to FIG. 7, an epitaxial layer 120 is formed on a substrate 101. The epitaxial layer 120 may be formed by, for example, epitaxial growth. After that, a first plurality of trenches (not illustrated) and one or more second trenches (not illustrated) extending downward from an uppermost surface of the epitaxial layer 120 may be formed. For example, the trenches may be formed by forming a mask pattern on the epitaxial layer 120 and then etching exposed areas of the epitaxial layer 120. The first trenches may be a deep trench, and the second trench may be a shallow trench. Thus, the first and second trenches may be formed separately. The first trench is for the pillars 130, and the second trench(es) are for the floating region(s) 170. Thereafter, the pillars 130 and the floating region(s) 170 are formed. For example, a semiconductor material containing first conductivity type impurities may be deposited in the first and second trenches and on the epitaxial layer 120, after which the epitaxial layer 120 may be polished (e.g., by chemical-mechanical polishing [CMP]) to expose an upper surface of the epitaxial layer 120. The semiconductor material remains in the trenches. In a further embodiment, the semiconductor material deposition and CMP process may be alternatingly and repeatedly performed (e.g., in successive layers) until the first trenches are completely filled.

Alternatively, the pillars 130 and the floating region 170 may be formed by successively forming (e.g., by epitaxial growth) a plurality of second conductivity type epitaxial layers, forming a first conductivity type implant layer formed in a predetermined upper region of each of the epitaxial layers (e.g., by ion implantation of a first conductivity type dopant) after its deposition and prior to the deposition of the successive epitaxial layer), and diffusing and optionally activating the dopant (e.g., by heat treatment or thermal annealing). For example, when x successive epitaxial layers are grown, the ion implantation to form the pillars 130 may be conducted following y of the x epitaxial layer growth cycles, and the ion implantation to form the floating region 170 may be conducted during z of they ion implantations, where x≥y±2, y≥2z, and z is an integer of 1 or more. Thus, y is an integer of at least 2, and x is an integer of at least 4.

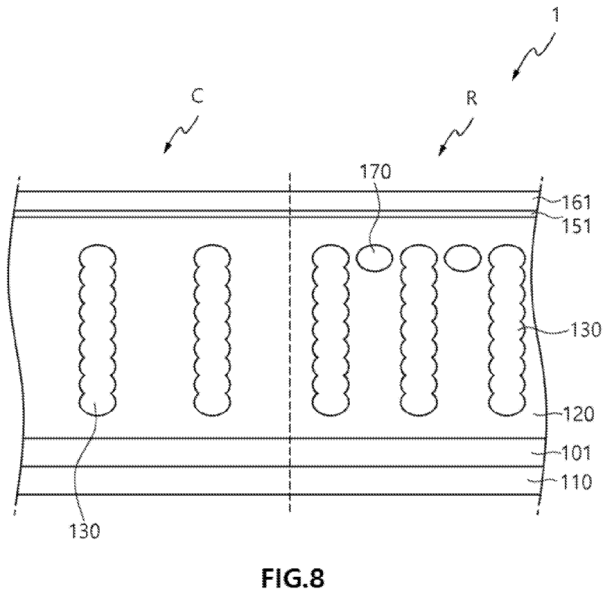

Referring to FIG. 8, an insulating layer 151 is formed on the epitaxial layer 120, and a gate layer 161 is formed on the insulating layer 151. The insulating layer 151 may comprise silicon dioxide, a high-k dielectric, or a combination thereof. The gate layer 161 may be or comprise a conductive polysilicon layer. Thereafter, the gate oxide layer 150 and the gate electrode 160 are formed by forming a mask pattern on the gate layer 161 and sequentially etching the gate layer 161 and the insulating layer 151.

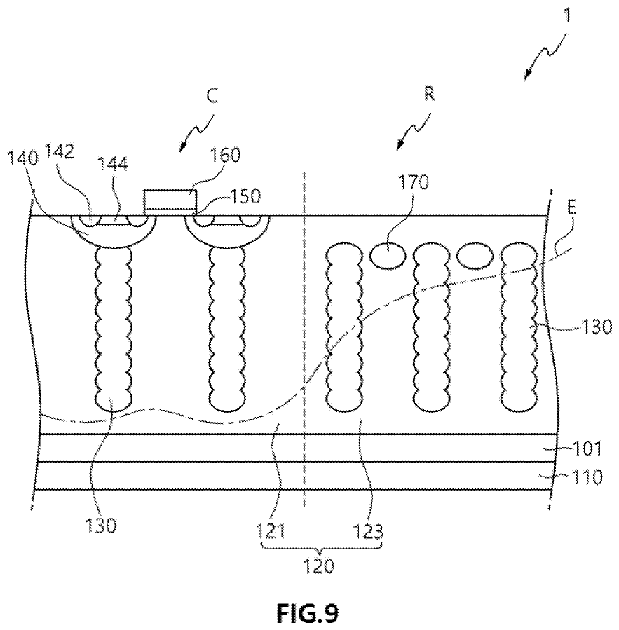

Referring to FIG. 9, a body region 140 is formed by implanting first conductivity type impurities in an upper portion of each pillar 130 in a cell region C in the presence of a mask. The gate electrode 160 may also serve as a mask pattern. After second conductivity type impurities for forming a source 142 are implanted in the body region 140, first conductivity type impurities are implanted therein overlapping the second conductivity type impurities (e.g., for the source region 142). As a result, the source 142 and a body contact 144 are formed.

The foregoing detailed descriptions may be merely an example of the present disclosure. Also, the inventive concept is explained by describing various embodiments and can be used through various combinations, modifications, and environments. That is, the inventive concept may be amended or modified without departing from the scope of the technical idea and/or knowledge in the art. The foregoing embodiments are for illustrating the best mode for implementing the technical idea of the present disclosure, and various modifications may be made therein according to specific application fields and uses of the present disclosure. Therefore, the foregoing detailed description of the present disclosure is not intended to limit the inventive concept to the disclosed embodiments.

What is claimed is:

1. A superjunction semiconductor device, comprising:
a substrate;
first and second epitaxial layers on the substrate, the first epitaxial layer in a cell region and the second epitaxial layer in a ring region;
a plurality of pillars spaced apart from each other in a transverse direction in the first epitaxial layer and the second epitaxial layer;
a body region on each of the pillars in the first epitaxial layer;
a source in the body region;
a gate electrode on the first epitaxial layer; and
a floating region in the second epitaxial layer between adjacent pillars in the ring region.

2. The superjunction semiconductor device of claim 1, wherein the floating region has substantially a same doping concentration as the pillars.

3. The superjunction semiconductor device of claim 1, wherein the floating region has a predetermined length in a longitudinal direction in the ring region.

4. The superjunction semiconductor device of claim 3, wherein the predetermined length of the floating region is less than that of the adjacent pillars along the longitudinal direction in the ring region.

5. The superjunction semiconductor device of claim 1, wherein the floating region is in the ring region at a position adjacent to the cell region.

6. The superjunction semiconductor device of claim 5, wherein the floating region has an end thereof adjacent to or in contact with a boundary between the ring region and the cell region.

7. A superjunction semiconductor device, comprising:
a substrate;
a second conductivity type epitaxial layer on the substrate, including a first epitaxial layer in a cell region and a second epitaxial layer in a ring region;
a plurality of first conductivity type pillars alternating with portions of the epitaxial layer, spaced apart from each other in a transverse direction in the first epitaxial layer and the second epitaxial layer;
a first conductivity type body region on each of the pillars in the first epitaxial layer;
a second conductivity type source in the body region;
a gate electrode on the first epitaxial layer; and
a floating region in the second epitaxial layer between adjacent pillars in the ring region,
wherein the floating region has an uppermost surface substantially flush with uppermost surfaces of the adjacent pillars and a vertical thickness or height equal to or less than half of that of the adjacent pillars.

8. The superjunction semiconductor device of claim 7, wherein the floating region has a dose ratio of P-type to N-type impurities equal to or less than 1.

9. The superjunction semiconductor device of claim 7, further comprising:
a body contact in the body region adjacent to or in contact with the source; and
a gate oxide layer between the gate electrode and the first epitaxial layer.

10. The superjunction semiconductor device of claim 9, wherein the floating region is between the adjacent pillars in the ring region adjacent to the cell region, and
the floating region has a length in the longitudinal direction less than that of the adjacent pillars in the longitudinal direction.

11. The superjunction semiconductor device of claim 89, wherein the floating region is in a ring Y region or a ring corner region.

12. A method of manufacturing a superjunction semiconductor device, the method comprising:
forming a first epitaxial layer and a second epitaxial layer on a substrate;
forming a plurality of pillars in the epitaxial layer, spaced apart from each other in a transverse direction;
forming a gate oxide layer on the first epitaxial layer;
forming a gate electrode on the gate oxide layer; and
forming a floating region between adjacent pillars in the second epitaxial layer.

13. The method of claim 12, wherein the floating region is formed at a position corresponding to upper portions of the adjacent pillars.

14. The method of claim 12, wherein the floating region and the pillars are formed contemporaneously.

15. The method of claim 14, wherein an uppermost surface of the floating region is substantially flush with uppermost surfaces of the adjacent pillars, and a vertical thickness or height of the floating region is less than that of the adjacent pillars.

16. The method of claim 14, wherein a length of the floating region in a longitudinal direction is less than that of the adjacent pillars in the longitudinal direction in a ring region.

17. A method of manufacturing a superjunction semiconductor device, the method comprising:
forming a second conductivity type epitaxial layer including a first epitaxial layer and a second epitaxial layer on a substrate;
forming a plurality of first conductivity type pillars in the epitaxial layer, spaced apart from each other in a transverse direction;
forming a gate oxide layer on the first epitaxial layer;
forming a gate electrode on the gate oxide layer; and
forming a first conductivity type floating region between adjacent pillars in the second epitaxial layer,
wherein the floating region is adjacent to a cell region and has a dose ratio of P-type to N-type impurities equal to or less than 1.

18. The method of claim 17, wherein the floating region has a predetermined length equal to or less than half of that of the adjacent pillars, an uppermost surface of the floating region is substantially flush with uppermost surfaces of the adjacent pillars, and a vertical thickness or height of the floating region is equal to or less than half of that of the adjacent pillars.

19. The method of claim 17, further comprising:
forming a second conductivity type source in each body region; and
forming a first conductivity type body contact adjacent to or in contact with the source.

20. The method of claim 19, wherein the body contact is formed in a center of the source, thereby separating the source into two source regions in the transverse direction.
